(19) United States
(12) Patent Application Publication
(10) Pub. No.: US 2021/0066518 A1
(43) Pub. Date: Mar. 4, 2021

(54) METALLIZATION METHOD FOR A SEMICONDUCTOR WAFER

(71) Applicant: AZUR SPACE Solar Power GmbH, Heilbronn (DE)

(72) Inventors: Wolfgang KOESTLER, Heilbronn (DE); Benjamin HAGEDORN, Ellhofen (DE)

(73) Assignee: AZUR SPACE Solar Power GmbH, Heilbronn (DE)

(21) Appl. No.: 17/007,711

(22) Filed: Aug. 31, 2020

(30) Foreign Application Priority Data
Aug. 29, 2019 (DE) 10 2019 006 098.9
Mar. 2, 2020 (DE) 10 2020 001 342.2

(51) Int. Cl. H01L 31/0224

(52) U.S. Cl. CPC H01L 31/02245; H01L 31/0687

(57) ABSTRACT

A metallization method for a semiconductor wafer having at least the steps: providing a semiconductor wafer having a top side and a bottom side and comprising a plurality of solar cell stacks, wherein each solar cell stack has a Ge substrate forming the bottom side of the semiconductor wafer, a Ge subcell, and at least two III-V subcells in the order mentioned, as well as at least one through-hole, extending from the top side to the bottom side of the semiconductor wafer, with a continuous side wall and a circumference that is oval in cross section, applying a photoresist layer in certain areas as a resist pattern by means of a printing method to the top side and/or to bottom side of the semiconductor wafer, applying a metal layer in a planar manner to exposed regions of the surface of the semiconductor wafer.

This nonprovisional application claims priority under 35 U.S.C. § 119(a) to German Patent Application No. 10 2019 006 098.9, which was filed in Germany on Aug. 29, 2019, and German Patent Application No. 10 2020 001 342.2, which was filed in Germany on Mar. 2, 2020 and which is herein incorporated by reference.

### BACKGROUND OF THE INVENTION

### Field of the Invention

The present invention relates to a metallization method for a semiconductor wafer.

### Description of the Background Art

Different methods for metallizing semiconductor wafers are known. The desired metal structure is produced, for example, with the aid of a resist mask from positive resist or from negative resist, wherein the metal is applied in a planar manner, e.g., by means of physical vapor deposition. Alternatively, printing methods are used, e.g., screen printing or dispensing heads, which apply only the desired metal structure directly.

In order to reduce the shadowing of the front side of a solar cell, it is possible to contact the front side from the back side by means of a through-contact hole. Such solar cells are also known as metal wrap through (MWT) solar cells.

In addition to different production methods for the through-contact holes, different metallization methods are also known in order to achieve, in particular, reliable metallization in the area of the through-contact hole.

A production process for a MWT single solar cell made of multicrystalline silicon is known from “The Metal Wrap Through Solar Cell—Development and Characterization,” F. Clement, dissertation, February 2009, wherein the through-contact holes are produced using a UV laser or an IR laser in an mc-Si substrate layer.

Only then is an emitter layer produced by means of phosphorus diffusion along the top side, the side surfaces of the through-contact hole, and the bottom side of the solar cell. The through-contact hole is filled with a conductive via paste, e.g., a silver paste, by means of screen printing.

An inverted grown GaInP/AlGaAs solar cell structure with through-contact holes is known from “III-V multi-junction metal-wrap-through (MWT) concentrator solar cells,” E. Oliva et al., Proceedings, 32^{nd} European PV Solar Energy Conference and Exhibition, Munich, 2016, pp. 1367-1371, wherein the solar cell structure with the p-n junctions is grown epitaxially and the through-contact holes are only then produced by means of dry etching. A side surface of the through-hole is then coated with an insulation layer and the through-hole is then filled with copper by electroplating.

A solar cell stack made up of multiple III-V subcells on a GaAs substrate with a back-contacted front side is known from U.S. Pat. No. 9,680,035 B1, wherein a hole extending from the top side of the solar cell through the subcells into a substrate layer that has not yet been thinned is produced by means of a wet chemical etching process.

The etching process is based on the fact that the etch rates do not differ significantly, at least for the different III-V materials used in the solar cell stack. The hole is only opened downwards by thinning the substrate layer. Passivation and metallization of the front side and the hole are carried out before the substrate layer is thinned.

### SUMMARY OF THE INVENTION

It is therefore an object of the present invention to provide a device that refines the state of the art.

According to an exemplary embodiment of the invention, a metallization method for a semiconductor wafer is provided, comprising at least the steps: providing a semiconductor wafer having a top side and a bottom side and comprising a plurality of solar cell stacks, wherein each solar cell stack has a Ge substrate forming the bottom side of the semiconductor wafer, a Ge subcell, and at least two III-V subcells in the order mentioned, as well as at least one through-hole, extending from the top side to the bottom side of the semiconductor wafer, with a continuous side wall and a circumference that is oval in cross section; applying a resist layer in certain areas as a resist pattern by means of a printing method to the top side or to the bottom side of the semiconductor wafer or both to the top side and the bottom side of the semiconductor wafer; applying a metal layer in a planar manner to exposed regions of the surface of the semiconductor wafer, said regions which are coated with the photoresist layer, and to the resist layer; and removing the resist pattern with the metal layer part located thereon from the semiconductor wafer.

The individual subcells of the solar cell stacks can each have a p-n junction and the layers following the substrate are epitaxially produced on top of one another and/or interconnected by means of a wafer bonding method.

A Ge subcell contains germanium or consists of germanium, wherein a layer consisting of germanium optionally also contains other substances, in particular dopants, but also impurities in addition to the germanium.

The same also applies to the III-V subcells, which have one or more materials from main groups III and V or consist of such materials.

The resist layer is applied particularly easily, quickly, reliably, and/or precisely and reproducibly by means of the printing method. In particular, the method makes it possible, for example, to reliably recess the through-contact holes.

An advantage of the method therefore is that a reliable metallization of the through-holes, therefore in particular of the side surfaces of the through-hole, and of a surface of the semiconductor wafer, therefore the top side and/or the bottom side, is made possible simultaneously in one step by means of a planar application of the metallization.

The metallization method is therefore particularly economical and reliable.

The more continuous the resist pattern is formed (i.e., the fewer individual, non-interconnected sections make up the resist pattern), the simpler and faster the removal process will be.

After the application of the photoresist layer and before the application of the metal layer, the photoresist layer can be finely patterned by means of a photolithographic method.

In other words, after a coarse patterning, therefore the application of the photoresist layer in certain areas by means of the printing method, a second patterning, i.e., a fine patterning, is carried out before the application of the metal layer by means of a photolithographic method. Fine structures in a range of a few micrometers can be reliably and reproducibly produced hereby. It is understood that the resist is a photopatternable resist.

The photoresist layer can be formed as a negative resist layer or as a positive resist layer, wherein the resist pattern is formed in each case as an inverse of a trace diagram.

The resist layer recesses the through-holes. This ensures a reliable coating of the side surfaces of the through-holes during the subsequent metallization.

The semiconductor wafer provided can have separation trenches, wherein the resist layer is applied to a surface of the separation trenches.

The printing method can be an inkjet method. It has been shown that a resist pattern can be produced particularly reliably and precisely by means of an inkjet method.

The through-holes of the semiconductor wafer provided can have a first diameter of at most 1 mm and at least 300 μm or at least 400 μm or at least 450 μm at an edge adjacent to the top side of the semiconductor wafer.

The through-holes can have a second diameter of at most 500 μm and of at least 50 μm or at least 100 μm at an edge adjacent to the bottom side of the semiconductor wafer.

The semiconductor wafer provided can have a total thickness of at most 300 μm and of at least 90 μm or of at least 150 μm or of at least 200 μm.

According to a further embodiment, the resist pattern has at least one auxiliary section extending to an edge of the semiconductor wafer, wherein the removal of the resist layer is started with the auxiliary section.

The resist pattern can be formed continuous on the bottom side of the semiconductor wafer and/or on the top side of the semiconductor wafer in each case at least in the area of each individual solar cell stack or over multiple solar cell stacks or over the entire bottom side of the semiconductor wafer.

The semiconductor wafer provided can have a dielectric insulation layer covering the side wall of the through-hole and a region, adjacent to the through-hole, on the top side of the semiconductor wafer and a region, adjacent to the through-hole, on the bottom side of the semiconductor wafer.

The method can be carried out first for the bottom side and then for the top side of the semiconductor wafer. The bottom side of the semiconductor wafer is thus metallized first according to the method.

The method is used for the top side of the same semiconductor wafer only after the method, i.e., the processes of coating, applying metal, and removing the resist layer, has been carried out completely for the bottom side.

Alternatively, the metallization of the top side is metallized using method steps that differ from the method.

Again, as an alternative, the method is always carried out alternately for the top side and the bottom side of the semiconductor wafer; i.e., each method step is carried out first for the top side and then for the bottom side or vice versa, before the subsequent method step follows accordingly.

Likewise, alternatively, the method is first used completely for the top side of the semiconductor wafer and then for the bottom side of the semiconductor wafer.

Further scope of applicability of the present invention will become apparent from the detailed description given hereinafter. However, it should be understood that the detailed description and specific examples, while indicating preferred embodiments of the invention, are given by way of illustration only, since various changes, combinations, and modifications within the spirit and scope of the invention will become apparent to those skilled in the art from this detailed description.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 is a plan view of a semiconductor wafer;

FIG. 2 is a back side view of a solar cell stack back side metallized according to the metallization method;

FIG. 3 shows a sequence according to an exemplary embodiment of the invention of the metallization method;

FIG. 4 shows a cross section of a through-hole of a semiconductor wafer after the photoresist layer has been applied to the top side and the bottom side;

FIG. 5 shows a cross section of a through-hole of a semiconductor wafer after the photoresist layer has been removed from the top side and the bottom side;

FIG. 6 shows a cross section of a through-hole of a semiconductor wafer after the photoresist layer has been applied to the bottom side; and

FIG. 7 shows a cross section of a through-hole of a semiconductor wafer after the photoresist layer has been removed from the bottom side.

### DETAILED DESCRIPTION

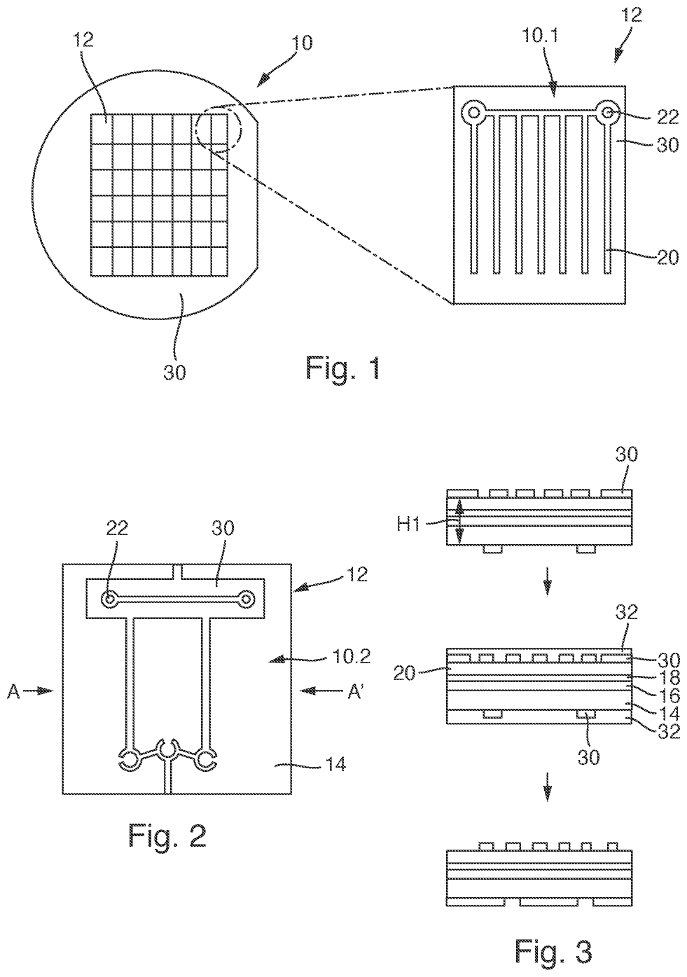

The diagrams in FIGS. 1 and 2 show a plan view and a back side detail of a semiconductor wafer 10 with a photoresist layer 30 applied according to the method.

Semiconductor wafer 10 has a top side 10.1, a bottom side 10.2, and multiple solar cell stacks 12, wherein each solar cell stack 12 has a Ge substrate 14 forming bottom side 10.2, a Ge subcell 16, a first III-V subcell 18, and a second III-V subcell 20 forming top side 10.1.

Each solar cell stack 12 also has two through-holes 22 extending from top side 10.1 to bottom side 10.2.

A photoresist layer 30 is applied as a resist pattern to top side 10.1 of semiconductor wafer 10, in this case therefore to the second III-V subcell 20, wherein the resist pattern in each case recesses an area around through-holes 22 and a plurality of linear areas for contact fingers and a busbar, connecting through-holes openings 22 and the contact fingers, per solar cell stack 12.

In this case, photoresist layer 30 extends in a planar manner to the edges of each solar cell stack and is connected across all solar cell stacks 12 of semiconductor wafer 10.

Photoresist layer 30, therefore, the resist pattern, also extends in a planar manner up to an edge of semiconductor wafer 10, so that the entire photoresist layer 30 can be removed in a continuous manner from top side 10.1 of semiconductor wafer 10 over the individual solar cell stacks.

On bottom side 10.2 of the semiconductor wafer, therefore Ge substrate 14, the resist pattern of photoresist layer 30 has an area surrounding the through-holes per solar cell stack as well as connecting webs extending to the edge of the individual solar cell stack. In other words, the through-holes are recessed.

The connecting webs of adjacent solar cell stacks are interconnected, so that the resist pattern has a continuous structure at least along each row of solar cell stacks and can thereby be removed again in a continuous manner.

In a further refinement, which is not shown, the connecting webs at the end of a row of solar cell stacks are connected to an auxiliary section that extends up to the edge of the semiconductor wafer, so that they can be removed more easily from the edge.

The diagram in FIG. 3 shows a sequence of a metallization method for a semiconductor wafer 10 according to a first embodiment of the invention. The individual method steps are applied both to the top side and to the bottom side of the semiconductor wafer.

Semiconductor wafer 10 with a total layer thickness H1 is provided.

A photoresist layer 30 is applied as a resist pattern by means of a printing method to top side 10.1 and to bottom side 10.2 of semiconductor wafer 10. Photoresist layer 30 is therefore only applied in certain areas.

A metal layer 32 is then applied in a planar manner to top side 10.1 and to bottom side 10.2 of semiconductor wafer 10.

Metal layer 32 thus covers both photoresist layer 30 and the areas that are not covered by the photoresist layer 30 but are exposed on top side 10.1 and bottom side 10.2 of semiconductor wafer 10.

In a subsequent method step, photoresist layer 30 is removed together with the metal layer 32 part located on photoresist layer 30. A residual structure of metal layer 32 remains on top side 10.1 and bottom side 10.2 of semiconductor wafer 10, wherein the residual structure is a negative of the resist pattern.

Alternatively, and not expressly shown here, the method steps are applied only to the top side or only to the bottom side, and the respective other surface of the semiconductor wafer remains unchanged accordingly. According to another alternative embodiment, also not shown here, the method is first carried out completely for one of the surfaces of the semiconductor wafer, therefore for the bottom side or for the top side, whereas the other surface remains unchanged. The method is then applied to the still unchanged surface.

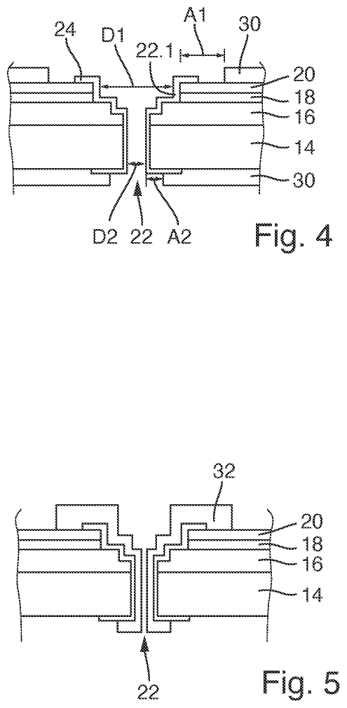

The diagram in FIG. 4 shows a cross section of a through-hole 22 of a semiconductor wafer 10 after photoresist layer 30 has been applied. Only the differences from the diagram in FIG. 3 will be explained below.

Through-hole 22 has a continuous side wall 22.1 and a circumference that is oval in cross section, a first diameter D1 on top side 10.1 of semiconductor wafer 10, and a second diameter D2 on bottom side 10.2 of semiconductor wafer 10.

Side wall 22.1 of through-hole 22 as well as a region, adjacent to through-hole 22, on top side 10.1 and a region, adjacent to through-hole 22, on bottom side 10.2 of semiconductor wafer 10 are coated with a dielectric insulation layer 24.

Photoresist layer 30 on top side 10.1 has a distance A1 from an edge of through-hole 22 and on bottom side 10.2 it has a distance A2 from an edge of through-hole 22.

Here, the distance A1 is so great that photoresist layer 30 on top side 10.1 of semiconductor wafer 10 is spaced apart from dielectric insulation layer 24. In other words, the through-holes are recessed during the application of photoresist layer 30.

The distance A2 is smaller than the distance A1 and is selected such that photoresist layer 30 on bottom side 10.2 of semiconductor wafer 10 also extends over an edge region of dielectric insulation layer 24.

The diagram in FIG. 5 shows a cross section of a through-hole 22 of a semiconductor wafer 10 after metal layer 32 has been applied and after photoresist layer 30, therefore the resist pattern, has been removed. Only the differences from the diagram in FIG. 4 will be explained below.

Metal layer 32 remaining after the resist pattern has been removed extends over side wall 22.1 of through-hole 22 and over part of dielectric insulation layer 24 on bottom side 10.2 of semiconductor wafer 10. Metal layer 32 is therefore spaced apart from the exposed, non-insulated surface of bottom side 10.2 of the semiconductor wafer.

On top side 10.1, metal layer 32 extends over dielectric insulation layer 24 to an exposed region, adjacent to dielectric insulation layer 24, on top side 10.1 of the semiconductor wafer. Metal layer 32 is thus integrally connected both to dielectric insulation layer 24 and to an exposed surface region of semiconductor wafer, here the second III-V subcell 20.

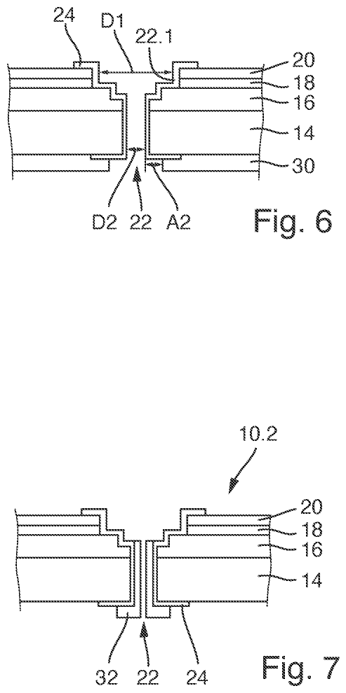

A further embodiment of the method of the invention is shown in the diagrams in FIGS. 6 and 7, wherein only the differences from FIGS. 3 to 6 are explained below.

The method is applied to bottom side 10.2 of the semiconductor wafer. FIG. 6 shows a cross section of one of through-holes 22 of semiconductor wafer 10 after photoresist layer 30 has been applied to the bottom side, whereas top side 10.1 remains unchanged, therefore in particular without photoresist layer 30.

The diagram in FIG. 7 shows a cross section of a through-hole 22 of a semiconductor wafer 10 after metal layer 32 has been applied to bottom side 10.2 and after photoresist layer 30, therefore the resist pattern, has been removed from bottom side 10.2. The remaining metal layer 32 covers part of bottom side 10.2, in particular a region formed by insulation layer 24 around through-hole 22 and a region of side wall 22.1 of the through-hole, said region being adjacent to bottom side 10.2. Top side 10.1 of the semiconductor wafer and a region of side wall 22.1 of through-hole 22, said region adjoining top side 10.1, are not covered by metal layer 32.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

What is claimed is:

1. A metallization method for a semiconductor wafer, the method comprising:
providing the semiconductor wafer having a top side and a bottom side and at least two solar cell stacks, each solar cell stack has a Ge substrate forming the bottom side of the semiconductor wafer, a Ge subcell, and at least two III-V subcells, and at least one through-hole extending from the top side to the bottom side of the semiconductor wafer with a continuous side wall and a circumference that is oval in cross section;
applying a photoresist layer in certain areas as a resist pattern via a printing method to the top side or to the bottom side or to the top and bottom sides of the semiconductor wafer;
applying a metal layer in a planar manner to exposed regions of the surface of the semiconductor wafer, the exposed regions being regions which are coated with the photoresist layer, and to the photoresist layer; and
removing the resist pattern with the metal layer part located thereon from the semiconductor wafer.

2. The method according to claim 1, wherein, after the application of the photoresist layer and before the application of the metal layer, the photoresist layer is finely patterned by a photolithographic method.

3. The method according to claim 1, wherein the photoresist layer is formed as a negative resist layer or as a positive resist layer, and wherein the resist pattern is formed in each case as an inverse of a trace diagram.

4. The method according to claim 1, wherein the resist layer recesses the through-holes.

5. The method according to claim 1, wherein the printing method is an inkjet method.

6. The method according to claim 1, wherein the through-holes of the semiconductor wafer provided have a first diameter of at most 1 mm and at least 300 μm or at least 400 μm or at least 450 μm at an edge adjacent to the top side of the semiconductor wafer, and have a second diameter of at most 500 μm and of at least 50 μm or at least 100 μm at an edge adjacent to the bottom side of the semiconductor wafer, and wherein the semiconductor wafer provided has a total thickness of at most 300 μm and of at least 90 μm or of at least 150 μm or of at least 200 μm.

7. The method according to claim 1, wherein the resist pattern has at least one auxiliary section extending to an edge of the semiconductor wafer, wherein the removal of the resist layer is started with the auxiliary section.

8. The method according to claim 1, wherein the resist pattern is formed continuous on the bottom side and/or on the top side of the semiconductor wafer in each case at least in an area of each individual solar cell stack or over multiple solar cell stacks or over the entire bottom side and/or top side of the semiconductor wafer.

9. The method according to claim 1, wherein the photoresist layer is finely patterned by a photolithographic method before the metal layer is applied.

10. The method according to claim 1, wherein the semiconductor wafer provided has a dielectric insulation layer covering the side wall of the through-hole and a region, adjacent to the through-hole, on the top side of the semiconductor wafer and a region, adjacent to the through-hole on the bottom side of the semiconductor wafer.

11. The method according to claim 1, wherein the method is carried out first for the bottom side and then for the top side of the semiconductor wafer.
